(19) United States
(12) Patent Application Publication
(10) Pub. No.: US 2012/0139014 A1
(43) Pub. Date: Jun. 7, 2012

(54) STRUCTURE AND METHOD FOR LOW TEMPERATURE GATE STACK FOR ADVANCED SUBSTRATES

(75) Inventors: Stephen W. Bedell, Wappingers Falls, NY (US); Sivananda Kanakasabapathy, Niskayuna, NY (US); Vijay Narayanan, New York, NY (US)

(73) Assignee: International Business Machines Corporation, Armonk, NY (US)

(21) Appl. No.: 12/958,354

(22) Filed: Dec. 1, 2010

(51) Int. Cl. H01L 29/772; H01L 21/336

(52) U.S. Cl. 257/288; 438/289; 257/E29.242; 257/E21.409

(57) ABSTRACT

A low-temperature metal gate stack for a field-effect transistor that is electrically activated at temperatures below 1000° C. The metal gate stack is composed of low melting materials that can be deposited by physical vapor deposition (PVD) onto a substrate.

### FIELD OF THE DISCLOSURE

The present disclosure relates to a germanium channel field-effect transistor (FET) having a metal gate stack of metals or metallic materials, which is electrically activated at temperatures below those typically used for the activation of polycrystalline silicon (poly-Si).

### BACKGROUND

Ongoing efforts are being made to improve the performance of semiconductor devices, such as field-effect transistors (FETs) by enhancing carrier mobility. One approach is to replace silicon in the channel region with materials having higher carrier mobility resulting in increased device performance. For example, germanium (Ge) may be used instead, which has a bulk electron mobility that is approximately twice as large as the bulk electron mobility of silicon. The hole mobility of Ge is about four times as large as the hole mobility of Si. Thus, the device performance, such as the drive current, of a semiconductor device with a given geometry, such as the channel length, may be increased simply by selecting Ge instead of Si as the channel material.

However, the melting point of Ge is 938° C., which is below processing temperatures often used in silicon semiconductor processing, such as the electrical activation of dopants in the poly-Si channel of gate semiconductor structures. Thus, the structural integrity of a gate stack comprising Ge or a Ge alloy cannot be maintained if a high temperature electrical activation step is required. Further, lowering the temperature of the annealing steps in conventional Si-based processing results in insufficient electrical activation of the poly-Si gate and crystalline Si substrate regions. By contrast, dopants in Ge can be electrically activated at temperatures below 700° C.

Additionally, at elevated temperatures the upward diffusion of Si into the Ge channel increases substantially, resulting in undesirable changes to the lattice structure and electrical properties of the Ge channel layer.

Moreover, the gate structure has to be able to withstand subsequent processing steps. For example, features of controlled size can be obtained in a reactive ion etching (RIE) process step. However, without a careful selection of processing conditions and provision of auxiliary structures, such as sidewall layers, the gate metal and/or the gate channel may be attacked by the RIE.

### SUMMARY OF THE DISCLOSURE

Accordingly, this disclosure provides for a structure and a method for advanced substrates that encompass metallic gate materials having a substantially lower electrical activation temperature than poly-Si.

Specifically, described herein is a conductive metal gate stack that can be formed at low-temperature, which comprises a semiconductor channel on a substrate; a barrier layer on the semiconductor channel; a metallic gate on the barrier layer; an upper layer on the metallic gate; a top layer on the upper layer; and a salicidization layer on the top layer, wherein electrical activation of the metallic gate is performed at 700° C. or below.

Further described herein is a method of forming a metal gate stack at low-temperature, which comprises providing a substrate; forming a semiconductor channel on the substrate; forming a barrier layer on the semiconductor channel; forming a metallic gate on the barrier layer; forming an upper layer on the metallic gate; and forming a top layer on the upper layer; wherein a maximum temperature during the forming of the low-temperature metal gate stack is about 700° C. or less.

### BRIEF DESCRIPTION OF THE DRAWINGS

FIG. 1 shows a substrate 100 including source region 120 and drain region 130 adjacent to channel region 140.

FIG. 2 shows barrier layer 210 being applied onto substrate 100.

FIG. 3 shows a metallic gate 310 being applied onto barrier layer 210.

FIG. 4 shows upper layer 410 being applied onto metallic gate 310.

FIG. 5 shows top layer 510 being applied onto upper layer 410.

FIG. 6 shows sidewall spacers 610 being applied onto the metal gate structure formed.

FIG. 7. shows a salicidation layer being applied over the metal gate structure formed.

FIG. 8 shows a scanning electron microscope (SEM) image of a field-effect transistor (FET) structure employing a poly-Ge gate electrode.

FIG. 9 shows a SEM image of a Ge channel FET after reactive ion etching of the metallic gate structure down to the barrier layer.

FIG. 10 shows a SEM image of a Ge channel FET after formation of gate sidewall spacers.

FIG. 11 shows a SEM image of a Ge channel FET having a gate channel length of about 85 nanometers.

FIG. 12 shows the drive current characteristics of the Ge channel FET depicted in FIG. 11.

### DESCRIPTION OF THE BEST AND VARIOUS EMBODIMENTS

The foregoing and other objects, aspects and advantages will be better understood from the following detailed description of the best and various embodiments.

The intermediate stages of manufacturing preferred embodiments of the present disclosure, which reduces the above-discussed adverse effects, are illustrated. Throughout the various views and illustrative embodiments of the present invention, like reference numbers are used to designate like elements.

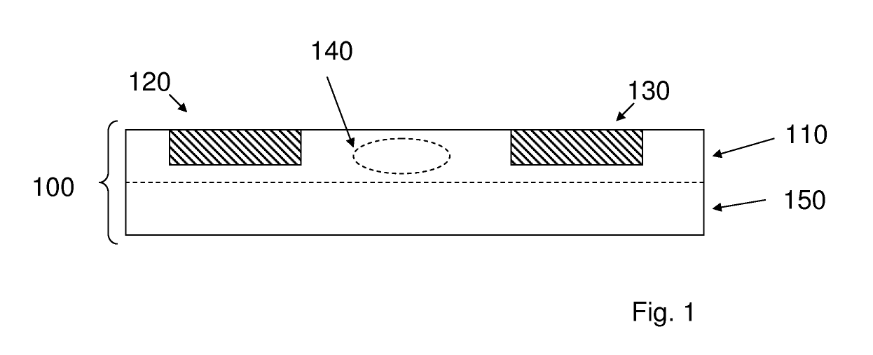

Turning to the drawings, FIG. 1 shows an early processing step in the formation of a Ge channel field effect transistor. A substrate 100 is provided with a source region 120, a drain region 130, and a channel region 140.

In one aspect of the disclosure, the Ge channel field effect transistors (FET) includes a n-type doped channel FET (nFET) or a p-type doped channel FET (pFET).

Substrate 100 typically comprises a layer of germanium (Ge) 110 on a semiconductor substrate 150. In another aspect of the disclosure, layer 110 is SiGe. In one embodiment, layer 110 is epitaxially grown Ge on semiconductor substrate 150. Typically, the semiconductor substrate 150 is a silicon wafer comprising bulk silicon, although other commonly used structures and materials such as silicon on insulator (SOI) can be used. Semiconductor substrate 150 may also be a III-V semiconductor, such as GaAs. In a typical embodiment, substrate 100 is a SOI or SiGe-on-insulator (SGOI) wafer. In another typical embodiment, a Ge layer is deposited onto a graded SiGe layer, which, in turn, is deposited onto a bulk Si wafer. Substrate 100 is typically lightly doped.

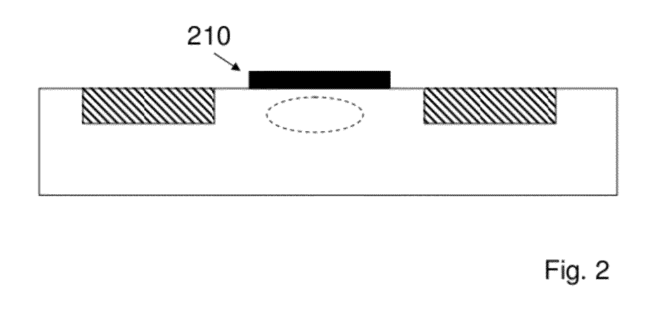

FIG. 2 depicts the formation of barrier layer 210 onto substrate 150. Barrier layer 210 is located adjacent to channel region 140. Typically, barrier layer 210 is a dielectric material, such as HfO₂. Barrier layer 210 may also be selected from ZrO₂ and SiO₂. Typically, barrier layer 210 has a thickness of from about 0.5 nanometer to about 10 nm. With particularity, barrier layer 210 is from about 1 to about 5 nm thick.

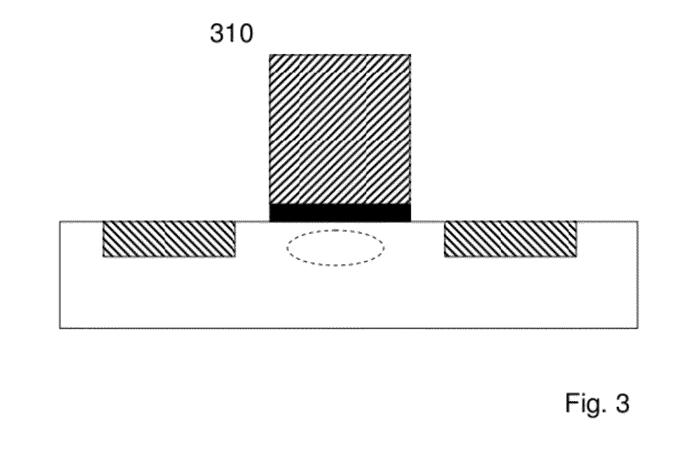

As depicted in FIG. 3, a metallic gate 310 is provided on barrier layer 210. The material for the metallic gate 310 may be a metal, a metal alloy, a metal silicide, a metal nitride, or a metal silicon nitride. Typically, metallic gate 310 is Ta, TaN, Ti, TiN, TiSiN or TaSiN.

The FET workfunction Φ and threshold voltage Vt can be adjusted by varying one or more of the material, the material composition, and the thickness of metallic gate 310.

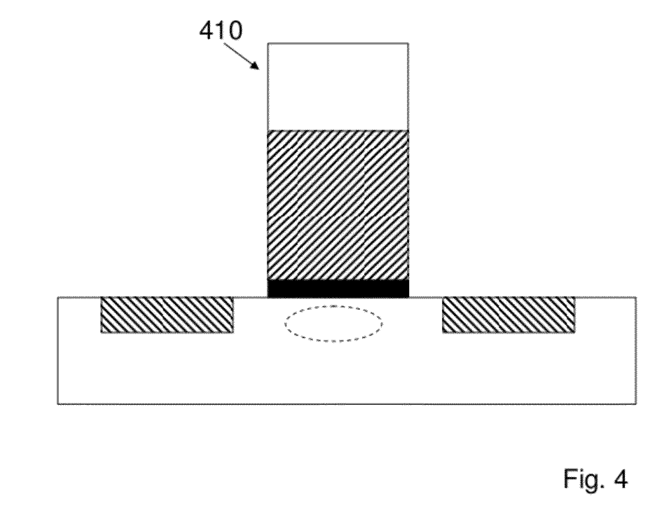

FIG. 4 depicts the depositing of upper layer 410 onto metallic gate 310. Upper layer 410 acts as a conductive layer, diffusion barrier, and seals the gate stack. Upper layer 410 may be a metal, a metal alloy, a metal silicide, a metal nitride, or a metal silicon nitride. Typically, upper layer 410 is Ta, TaN, Ti, TiN, TiSiN or TaSiN.

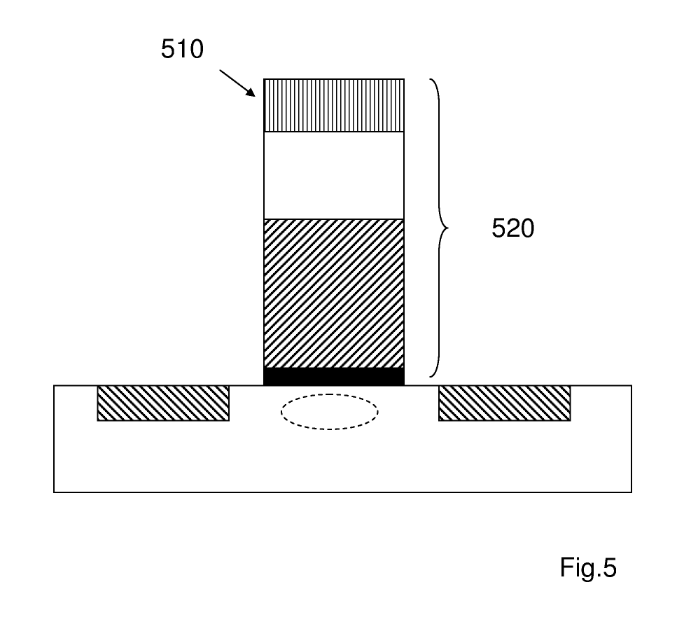

As depicted in FIG. 5, top layer 510 is deposited onto upper layer 410. Typically, top layer 510 is a silicon or a silicon-germanium alloy layer deposited by physical vapor deposition (PVD) or by chemical vapor deposition (CVD). Also typically, top layer is a silicon containing metal.

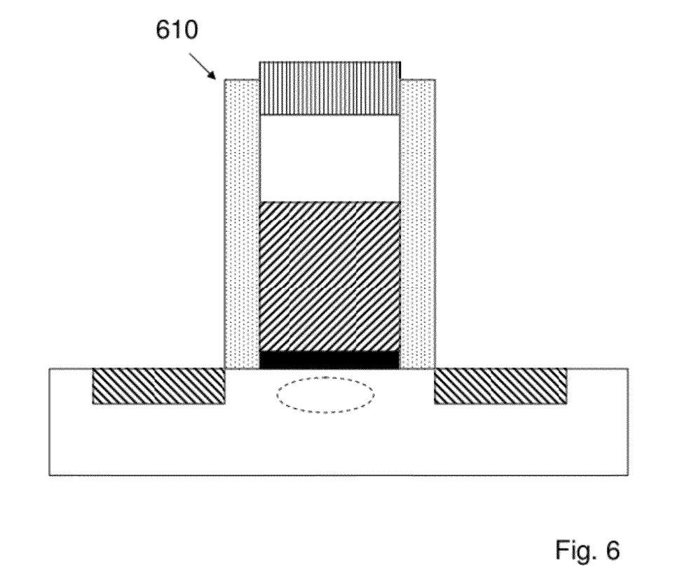

In FIG. 6 the deposition of side wall spacer 610 onto the flanks of the gate structure is shown. Side wall spacer 610 improves positioning of the location of the source and drain (S/D) junctions with respect to the gate as well as preventing electrical conduction between the gate and the S/D regions after the salicidation step.

Typically, the side wall spacer is a film of silicon dioxide, silicon nitride or combinations thereof. Also typically, the side wall spacers are formed in the following manner. A silicon oxide film is formed over the entire gate structure 520 and the source region 120 and the drain region 130. Subsequently, the semiconductor structure is anisotropically etched to remove the silicon oxide film on flat surfaces and to leave the silicon oxide film only on the side walls of the gate structure 520.

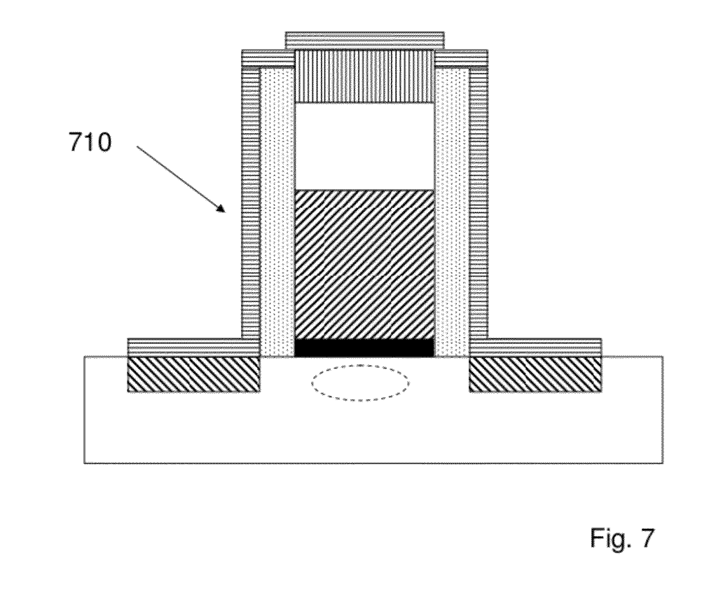

FIG. 7 depicts the application of a self-aligned silicidization (salidicization) layer 710 onto the metal gate stack. Typically, salidization layer 710 is provided by blanket deposition onto the metal gate stack and the substrate 100. The salidization layer 710 serves to adjust the workfunction of source region 120 and/or of drain region 130. The metal is typically one of Ti, W, Co, Ni, Pt and Pd, with particularity one of Ti, W, Co and Ni. The metal may include an alloying additive such as, for example, C, Al, Si, Sc, Ti, V, Cr, Mn, Fe, Co, Ni, Cu, Ge, Y, Zr, Nb, Mo, Ru, Rh, Pd, In, Sn, La, Hf, Ta, W, Re, Ir, Pt, Ce, Pr, Nd, Sm, Eu, Gd, Tb, Dy, Ho Tm, Yb, Lu and mixtures thereof. When present, the alloying additive is present in amounts up to about 50 atomic percent. The metal is formed by a conventional deposition process including, for example, chemical vapor deposition, plasma enhanced chemical vapor deposition, plating, sputtering, chemical solution deposition, atomic layer deposition, physical vapor deposition and other like techniques. The alloying additive can be formed at the same time as the metal or it can be adding to the metal after deposition thereof, or it can be co-deposited atop the metal in a separate layer.

The thickness of the deposited metal can vary. Typically, the resulting salicidation layer has a thickness from about 5 to about 15 nanometer.

A typical salicidation layer is Ni or Ni-containing deposited layer, which, after depositing, is thermally treated to chemically react with the underlying semiconductor regions (Ge, Si or SiGe). The unreacted salicidation layer is then selectively etched off using wet chemical processing or reactive ion etching. Example wet chemistry processes include treating the unreacted salicidation layer with nitric acid, hydrochloric acid, and mixtures and dilutions thereof.

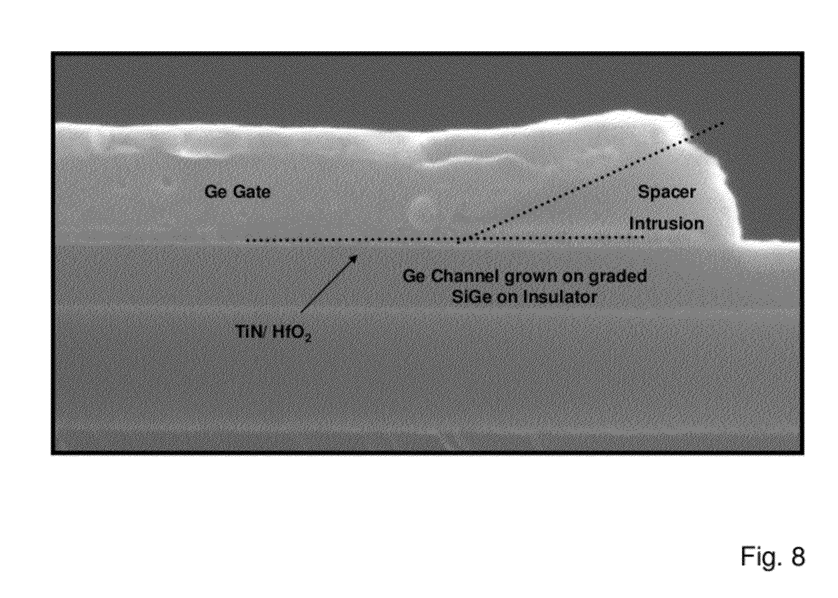

FIG. 8 shows a SEM image of an attempt to use a poly-Ge gate stack that has been subjected to Ge FET processing conditions, i.e., temperatures, chemicals and etching steps typically used for a Ge FET fabrication process. The removal of the Ge gate material at the sidewall indicates that although poly-Ge can be activated at a low temperature, poly-Ge is chemically too reactive to enable gate length scaling (shrinking) which is required in modern IC manufacturing.

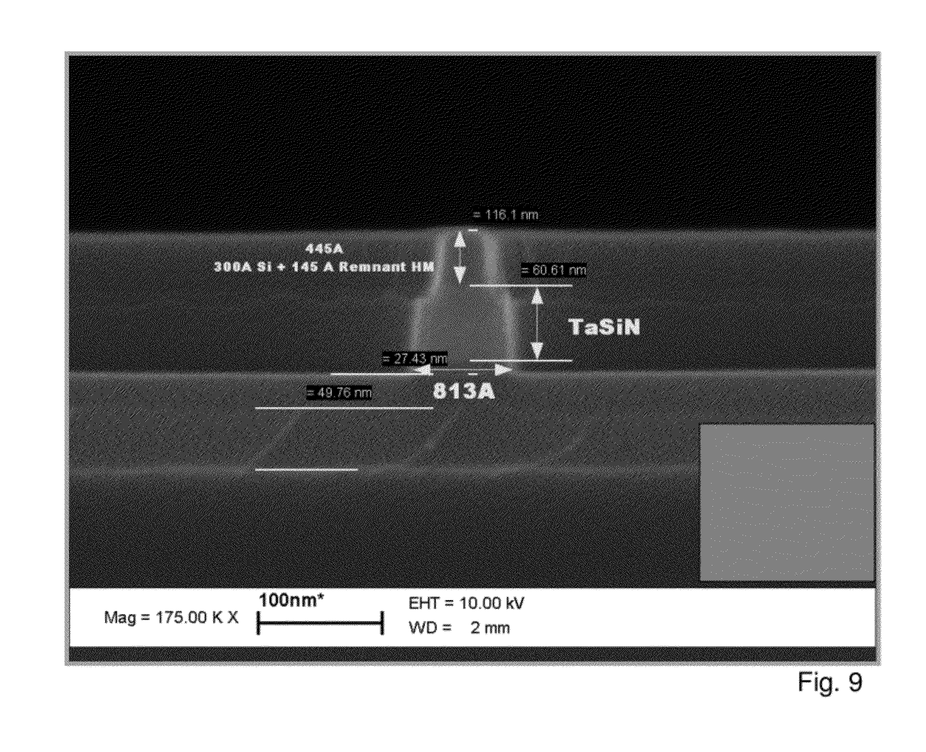

FIG. 9 depicts a metal gate stack after reactive ion etching the exposed gate structure down to the barrier layer 210. In this example, a thin oxide layer (hardmask) was used to define the gate regions during etching. However, other masking materials such as silicon nitride, photoresist, or other hydrocarbon layers are herein contemplated.

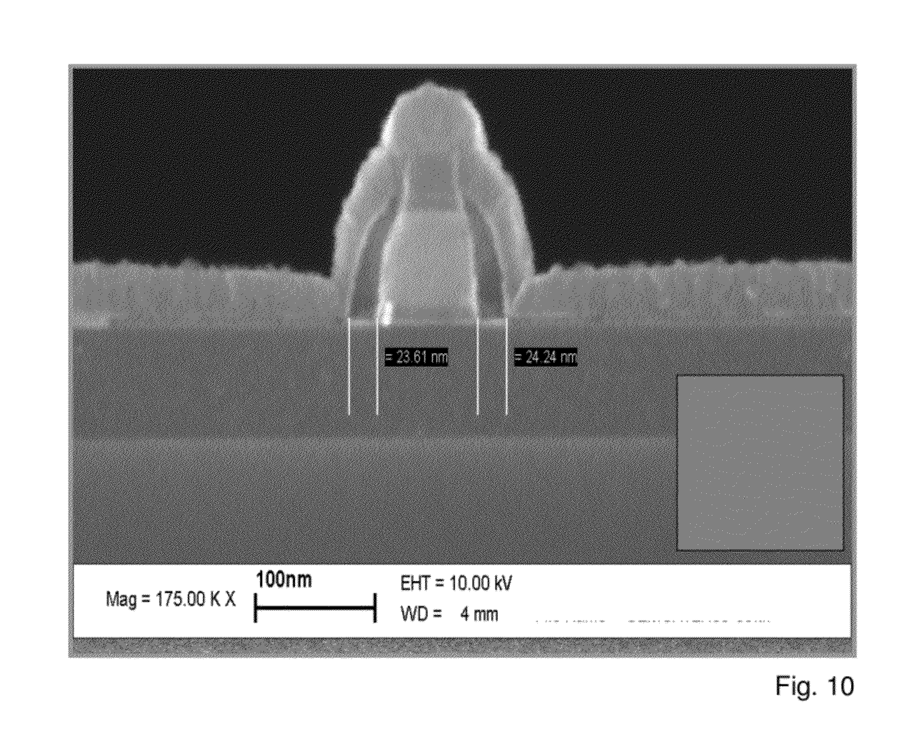

FIG. 10 depicts a metal gate stack after gate sidewall spacer formation. The thickness of the sidewall spacer of the nFET device in FIG. 10 is from about 23.6 nanometer to about 24.2 nanometer. Typically, the sidewall spacer thickness is from about 15 to about 30 nanometer.

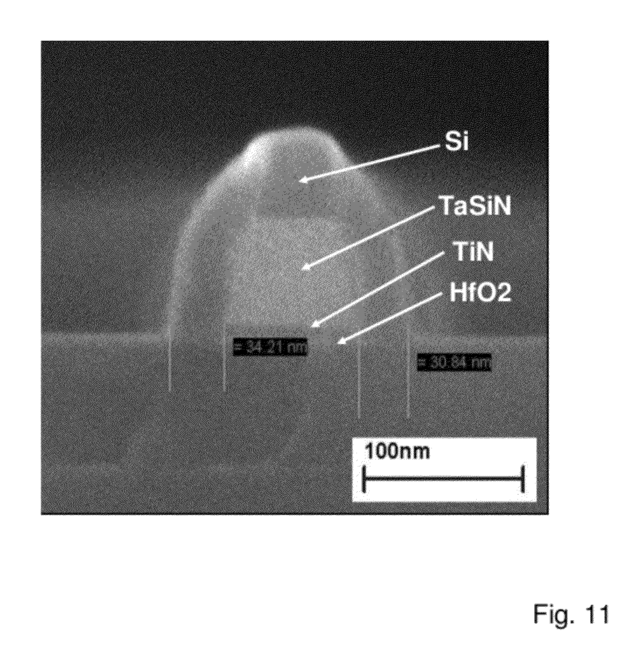

FIG. 11 depicts an all metal gate comprising a HfO₂ barrier layer, a titanium nitride (TiN) metallic gate, a tantalum silicon nitride (TaSiN) upper layer, and a Si top layer. The Si top layer may be partially or completely converted into a salicidation layer. In a preferred embodiment, the top layer is completely converted into a salicide layer (NiSi, NiSiGe, etc.). Although FIG. 11 depicts an exemplary embodiment with a Si top layer, SiGe alloys, either doped or undoped, are specifically contemplated in this disclosure.

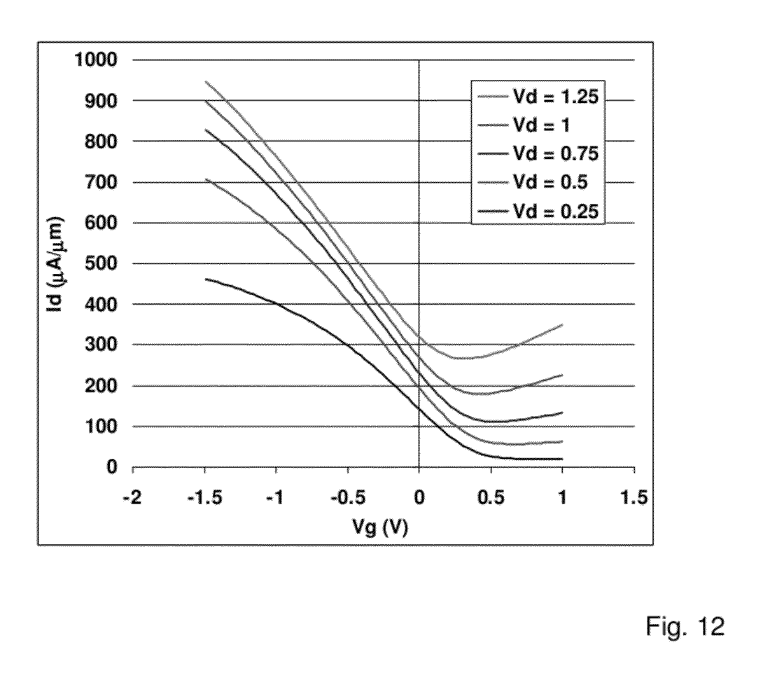

FIG. 12 depicts the short channel data of a Ge channel p-FET device with a 85 nanometer gate length. Drive currents Id have been measured for a drive voltage Vd of 1.25 V (top line) to a drive voltage Vd of 0.25 V (bottom line) in 0.25 V increments. The threshold voltage of the pFET is about 0.4 V.

The dopants in the channel region and/or the source/drain regions are electrically activated by a thermal activation process. Typically, the electrical activation is performed at a temperature below 700° C. With particularity, the temperature is of from 500 to 650° C. Also typically, the electrical activation is performed for about 1 to 30 minutes, with particularity for about 1 to 5 minutes.

Typically, the channel region is doped with a n-type or a p-type dopant resulting in the formation of an pFET and a nFET, respectively. Typical p-type dopants are aluminum, boron, gallium, and indium. Typical n-type dopants are antimony, phosphorous and arsenic. Typical dopant dosage is between about 1E16/cm³ and about 2E18/cm³.

The embodiments described hereinabove are further intended to explain best modes known of practicing it and to enable others skilled in the art to utilize the disclosure in such, or other, embodiments and with the various modifications required by the particular applications or uses. Accordingly, the description is not intended to limit it to the form disclosed herein. Also, it is intended that the appended claims be construed to include alternative embodiments.

The foregoing description of the disclosure illustrates and describes the present disclosure. Additionally, the disclosure shows and describes only the preferred embodiments but, as mentioned above, it is to be understood that the disclosure is capable of use in various other combinations, modifications, and environments and is capable of changes or modifications within the scope of the concept as expressed herein, commensurate with the above teachings and/or the skill or knowledge of the relevant art.

The term “comprising” (and its grammatical variations) as used herein is used in the inclusive sense of “having” or “including” and not in the exclusive sense of “consisting only of.” The terms “a” and “the” as used herein are understood to encompass the plural as well as the singular.

All publications, patents and patent applications cited in this specification are herein incorporated by reference, and for any and all purpose, as if each individual publication, patent or patent application were specifically and individually indicated to be incorporated by reference. In the case of inconsistencies, the present disclosure will prevail.

What is claimed is:

1. A low-temperature electrically activated metal gate stack, comprising:
a semiconductor channel on a substrate;
a barrier layer on the semiconductor channel;
a metallic gate on the barrier layer;
an upper layer on the metallic gate;
a top layer on the upper layer; and
a salicidization layer on the top layer,
wherein the activation temperature of the metallic gate is 700° C. or below.

2. The low-temperature metal gate stack of claim 1, wherein the semiconductor channel is selected from the group consisting of Ge and SiGe.

3. The low-temperature metal gate stack of claim 2, wherein the semiconductor channel is Ge.

4. The low-temperature metal gate stack of claim 1, wherein the metallic gate is selected from the group consisting of Ta, TaN, Ti, TiN, TiSiN, and TaSiN.

5. The low-temperature metal gate stack of claim 4, wherein the semiconductor channel is Ge.

6. The low-temperature metal gate stack of claim 1, wherein the upper layer is selected from the group consisting of Ta, TaN, Ti, TiN, TiSiN, and TaSiN.

7. The low-temperature metal gate stack of claim 1, wherein the top layer is selected from the group consisting of silicon and silicon-germanium or a metal silicide thereof.

8. The low-temperature metal gate stack of claim 1, wherein the barrier layer is HfO₂.

9. The low-temperature metal gate stack of claim 1, wherein the barrier layer has a thickness of from about 0.5 nm to about 10 nm.

10. A method of forming a low-temperature metal gate stack, comprising:
providing a substrate;
forming a semiconductor channel on the substrate;
forming a barrier layer on the semiconductor channel;
forming a metallic gate on the barrier layer;
forming an upper layer on the metallic gate; and
forming a top layer on the upper layer;
wherein a maximum temperature during the forming of the low-temperature metal gate stack is about 700° C. or less.

11. The method of claim 10, further comprising setting a threshold voltage of the low-temperature metal gate stack by selecting a thickness of the metallic gate.

12. The method of claim 10, further comprising salicidizing the top layer.

13. The method of claim 12, further comprising performing a reactive ion etching (RIE).

14. The method of claim 10, wherein the forming the top layer comprises depositing the top layer by physical vapor deposition (PVD) or chemical vapor deposition (CVD).

15. The method of claim 10, further comprising performing an activation anneal of the semiconductor channel below the maximum temperature.

16. The method of claim 15, further comprising performing the activation anneal for a period of less than about 30 minutes.

17. The method of claim 10, further comprising doping the semiconductor channel with a dopant.

18. The method of claim 17, wherein the dopant is a p-dopant.

19. The method of claim 17, wherein the dopant is an n-dopant.

20. The method of claim 17, wherein the dopant is selected from the group consisting of boron, arsenic, indium, phosphorous, and aluminum.
